(19) United States
(12) Patent Application Publication
(10) Pub. No.: US 2024/0303399 A1
(43) Pub. Date: Sep. 12, 2024

(54) MACHINE LEARNING WORKFLOW TO PREDICT SANDING EVENTS

(71) Applicant: CHEVRON U.S.A. INC., San Ramon, CA (US)

(72) Inventor: Mustafa Can Kara, Covington, LA (US)

(21) Appl. No.: 18/546,132

(22) PCT Filed: Feb. 11, 2022
(86) PCT No.: PCT/US2022/016118

§ 371 Date: Aug. 11, 2023

Related U.S. Application Data
(60) Provisional application No. 63/148,736, filed on Feb. 12, 2021.

(51) Int. Cl. G06F 30/27

(52) U.S. Cl. CPC G06F 30/27

(57) ABSTRACT

An unsupervised machine-learning model is trained using historical operation characteristics of a well. Operation characteristics of the well for a duration of time is reconstructed by the unsupervised machine-learning model. Whether a sanding event will occur in the future at the well is predicted based on the difference between the operation characteristics of the well and the reconstructed operation characteristics of the well.

### CROSS-REFERENCE TO RELATED APPLICATION

The present application claims the benefit of U.S. Provisional Application No. 63/148,736, entitled “A Machine Learning Workflow to Predict Anomalous Sanding Events in Deepwater Wells,” which was filed on Feb. 12, 2021, the entirety of which is hereby incorporated herein by reference.

### FIELD

The present disclosure relates generally to the field of predicting sanding events in a well.

### BACKGROUND

During operation of a well (e.g., for production), sand may break away from the surrounding region and contaminate the well. Sand contamination in the well may cause damage to the well/equipment at the well and/or inhibit operation of the well/equipment at the well.

### SUMMARY

This disclosure relates to predicting sanding events. Well operation information and/or other information may be obtained. The well operation information may characterize operation characteristics of a well for a duration of time. Reconstructed operation characteristics of the well for the duration of time may be determined using an unsupervised machine-learning model. The unsupervised machine-learning model may be trained using historical well operation information and/or other information. The historical well operation information may characterize the operation characteristics of the well for a period of time preceding the duration of time. A future occurrence of a sanding event at the well may be predicted based on the operation characteristics of the well for the duration of time, the reconstructed operation characteristics of the well for the duration of time, and/or other information.

A system for predicting sanding events may include one or more electronic storage, one or more processors and/or other components. The electronic storage may store well operation information, information relating to a well, information relating to operation characteristics of the well, information relating to an unsupervised machine learning model, information relating to reconstructed operation characteristics of the well, historical well operation information, information relating to historical operation characteristics of the well, information relating to sanding events, information relating to prediction of sanding events, and/or other information.

The processor(s) may be configured by machine-readable instructions. Executing the machine-readable instructions may cause the processor(s) to facilitate predicting sanding events. The machine-readable instructions may include one or more computer program components. The computer program components may include one or more of a well operation component, a reconstruction component, a prediction component, and/or other computer program components.

The well operation component may be configured to obtain well operation information and/or other information. The well operation information may characterize operation characteristics of a well for a duration of time. In some implementations, the operation characteristics of the well may include pressure at the well, temperature at the well, and/or other operation characteristics of the well.

The reconstruction component may be configured to determine reconstructed operation characteristics of the well for the duration of time. The reconstructed operation characteristics of the well for the duration of time may be determined using one or more unsupervised machine-learning models. The unsupervised machine-learning model(s) may be trained using historical well operation information and/or other information. The historical well operation information may characterize the operation characteristics of the well for one or more periods of time preceding the duration of time.

In some implementations, the unsupervised machine-learning model may be retrained using the well operation information and/or other information.

In some implementations, the unsupervised machine-learning model(s) may include a linear unsupervised machine-learning model and/or a non-linear unsupervised machine-learning model. In some implementations, the linear unsupervised machine-learning model(s) may include a principal component analysis. In some implementations, the non-linear unsupervised machine-learning model(s) may include a long short-term memory autoencoder.

The prediction component may be configured to predict a future occurrence of a sanding event at the well. The future occurrence of the sanding event at the well may be predicted based on the operation characteristics of the well for the duration of time, the reconstructed operation characteristics of the well for the duration of time, and/or other information.

In some implementations, prediction of the future occurrence of the sanding event at the well based on the operation characteristics of the well for the duration of time and the reconstructed operation characteristics of the well for the duration of time may include: determination of an anomaly score based on a difference between the operation characteristics of the well for the duration of time and the reconstructed operation characteristics of the well for the duration of time; and prediction of the future occurrence of the sanding event at the well based on a comparison between the anomaly score and an anomaly score threshold.

In some implementations, the anomaly score threshold may be determined based on the operation characteristics of the well for the period of time, reconstructed operation characteristics of the well for the period of time, and/or other information. In some implementations, the anomaly score threshold may be determined based on the operation characteristics of the well for the period of time and reconstructed operation characteristics of the well for the period of time such that a threshold percentage of historical anomaly scores satisfies the anomaly score threshold.

In some implementations, one or more visualizations of the comparison between the anomaly score and the anomaly score threshold may be presented on one or more displays.

These and other objects, features, and characteristics of the system and/or method disclosed herein, as well as the methods of operation and functions of the related elements of structure and the combination of parts and economies of manufacture, will become more apparent upon consideration of the following description and the appended claims with reference to the accompanying drawings, all of which form a part of this specification, wherein like reference numerals designate corresponding parts in the various figures. It is to be expressly understood, however, that the drawings are for the purpose of illustration and description only and are not intended as a definition of the limits of the invention. As used in the specification and in the claims, the singular form of “a,” “an,” and “the” include plural referents unless the context clearly dictates otherwise.

### BRIEF DESCRIPTION OF THE DRAWINGS

FIG. 1 illustrates an example system for predicting sanding events.

FIG. 2 illustrates an example method for predicting sanding events.

FIG. 3 illustrates an example process for predicting sanding events.

FIG. 4 illustrates example acoustic sand detection and visualization of comparison between anomaly score and anomaly score threshold for sanding event prediction.

### DETAILED DESCRIPTION

The present disclosure relates to predicting sanding events in a well. An unsupervised machine-learning model is trained using historical operation characteristics of a well. Operation characteristics of the well for a duration of time is reconstructed by the unsupervised machine-learning model. Whether a sanding event will occur in the future at the well is predicted based on the difference between the operation characteristics of the well and the reconstructed operation characteristics of the well.

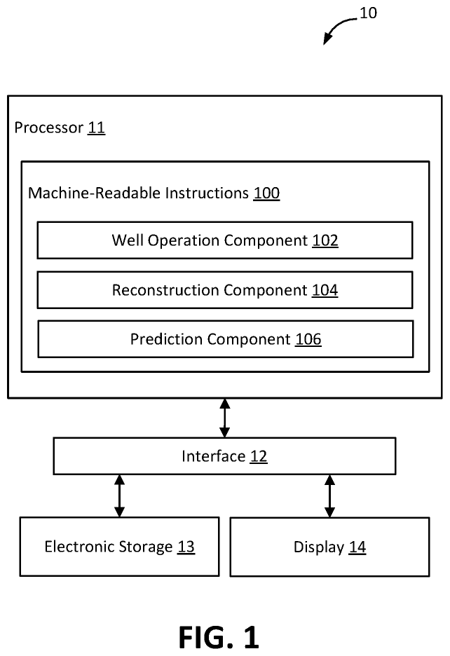

The methods and systems of the present disclosure may be implemented by a system and/or in a system, such as a system 10 shown in FIG. 1. The system 10 may include one or more of a processor 11, an interface 12 (e.g., bus, wireless interface), an electronic storage 13, a display 14, and/or other components. Well operation information and/or other information may be obtained by the processor 11. The well operation information may characterize operation characteristics of a well for a duration of time. Reconstructed operation characteristics of the well for the duration of time may be determined by the processor 11 using an unsupervised machine-learning model. The unsupervised machine-learning model may be trained using historical well operation information and/or other information. The historical well operation information may characterize the operation characteristics of the well for a period of time preceding the duration of time. A future occurrence of a sanding event at the well may be predicted by the processor 11 based on the operation characteristics of the well for the duration of time, the reconstructed operation characteristics of the well for the duration of time, and/or other information.

The electronic storage 13 may be configured to include electronic storage medium that electronically stores information. The electronic storage 13 may store software algorithms, information determined by the processor 11, information received remotely, and/or other information that enables the system 10 to function properly. For example, the electronic storage 13 may store well operation information, information relating to a well, information relating to operation characteristics of the well, information relating to an unsupervised machine learning model, information relating to reconstructed operation characteristics of the well, historical well operation information, information relating to historical operation characteristics of the well, information relating to sanding events, information relating to prediction of sanding events, and/or other information.

The display 14 may refer to an electronic device that provides visual presentation of information. The display 14 may include a color display and/or a non-color display. The display 14 may be configured to visually present information. The display 14 may present information using/within one or more graphical user interfaces. For example, the display 14 may present well operation information, information relating to a well, information relating to operation characteristics of the well, information relating to an unsupervised machine learning model, information relating to reconstructed operation characteristics of the well, historical well operation information, information relating to historical operation characteristics of the well, information relating to sanding events, information relating to prediction of sanding events, and/or other information.

A sanding event may refer to migration of sand into a well from the surrounding region. A sanding event may refer to sand in the surrounding region breaking away and entering the well. A sanding event may be referred to as sand production. For example, the pressure difference between the reservoir and the wellhead and/or the flow of fluids within the well/fractures may cause sand formations to come apart and to come into the fluid flowing within the well/fractures.

For example, deep-water wells may possess a high risk of sand escaping the reservoir into the production systems. Sand contamination in the well may result in potential well/equipment damage and/or contaminate the production of hydrocarbons from the well. Movement of sand along with the production fluid may cause erosive weaver to the well/equipment. Excessive sand erosion may cause blockage in tubulars and cavities in downhole equipment (e.g., choke valves, pipe elbows, tees, bends, etc.), and maintenance costs for subsea equipment may add up to millions of dollars yearly to operators.

The present disclosure provides a scalable unsupervised machine-learning model that utilizes historical and real-time feed of sensor data from a well to predict occurrence of sanding events in the future. The present disclosure allows sanding prediction to be provided before the well/equipment is damaged. The present disclosure utilizes linear and/or non-linear analysis of the sensor data to reconstruct the sensor data at the well. Comparison between the sensor data and the reconstructed sensor data may be used to determine an anomaly score for the well. Comparison between the historical sensor data and the reconstructed historical sensor data may be used to determine an anomaly score threshold for the well. The anomaly score and the anomaly score threshold may be stored in electronic storage (e.g., database, data server), which may be accessed by an operator to investigate the real-time data and/or by a visualization tool/software to provide visualization of the anomaly score and the anomaly score threshold.

A prediction of a future sanding event at the well may be made based on the anomaly score passing the anomaly score threshold. For example, based on the anomaly score passing the anomaly score threshold, a sanding event may be predicted to occur at the well within a certain duration of time (e.g., within minutes, within 1-2.5 hours). Based on a future sanding event being predicted at the well, one or more alarms (e.g., visible alarm, audible alarm) may be triggered, which may enable operators to take preventative/mitigative actions before damage to the well/equipment occurs. For example, based on the anomaly score being greater than the anomaly score threshold, a visible alarm (e.g., red coloring) may be presented on a display and/or a sound may be played. As another example, based on the anomaly score being greater than the anomaly score threshold, a notification (e.g., text notification, email notification) may be sent to an operator. Based on a future sanding event being predicted at the well, one or more preventative/mitigative measures may be automatically employed to reduce the likelihood of the sanding event in the future and/or to reduce damage to the well/equipment.

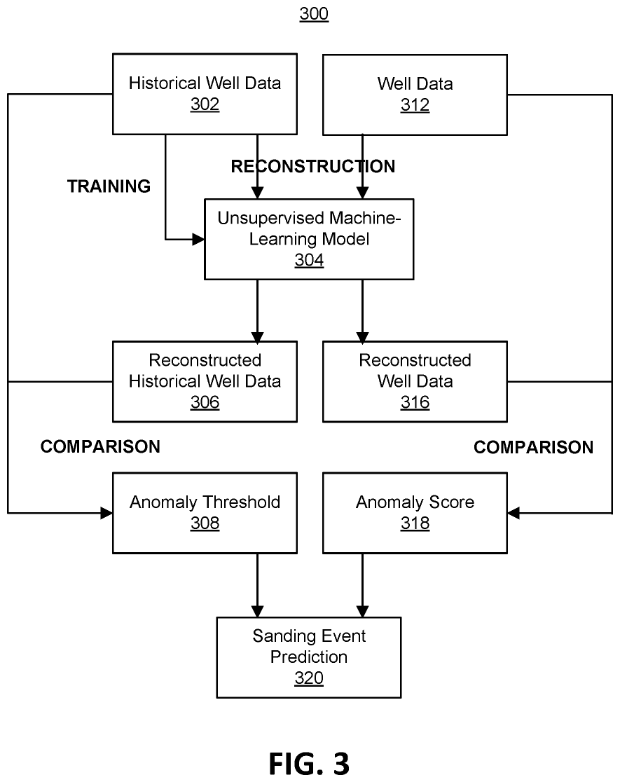

FIG. 3 illustrates an example process 300 for predicting sanding events. In the process 300, historical well data 302 and well data 312 may be obtained. The historical well data 302 may include historical sensor data measured at the well, such as pressure data and/or temperature data measured within the past six months to a year at the well. The well data 312 may include real-time sensor data measured at the well, such as pressure data and/or temperature data measured within the past day at the well. The historical well data 302 and the well data 312 may include time-series data of pressure and temperature measured at the well.

The historical well data 302 may be used to train an unsupervised machine-learning model 304. The unsupervised machine-learning model may include one or more linear unsupervised machine-learning models (e.g., principal component analysis) and/or one or more non-linear unsupervised machine-learning models (e.g., long short-term memory autoencoder).

Once trained, the unsupervised machine-learning model 304 may be used to reconstruct the sensor data measured at the well. The unsupervised machine-learning model 304 may receive as input the historical well data 302 and output reconstructed historical well data 306. The unsupervised machine-learning model 304 may receive as input the well data 312 and output reconstructed well data 316. The unsupervised machine-learning model 304 may output time-series data. Reconstructed data points in the time-series data output by the unsupervised machine-learning model 304 may correspond to the data points in the time-series data input to the unsupervised machine-learning model 304.

A comparison between the historical well data 302 and the reconstructed historical well data 306 may be performed to determine a value of an anomaly threshold 308 for the well. A comparison between the well data 312 and the reconstructed well data 316 may be performed to determine a value of an anomaly score 318 of the well. Based on the anomaly threshold 308 and the anomaly score 318, sanding event prediction 320 may be made. For example, based on the value of the anomaly score 318 being larger than the value of the anomaly threshold 308, a sanding event may be predicted to occur in the future at the well.

Referring back to FIG. 1, the processor 11 may be configured to provide information processing capabilities in the system 10. As such, the processor 11 may comprise one or more of a digital processor, an analog processor, a digital circuit designed to process information, a central processing unit, a graphics processing unit, a microcontroller, an analog circuit designed to process information, a state machine, and/or other mechanisms for electronically processing information. The processor 11 may be configured to execute one or more machine-readable instructions 100 to facilitate predicting sanding events. The machine-readable instructions 100 may include one or more computer program components. The machine-readable instructions 100 may include a well operation component 102, a reconstruction component 104, a prediction component 106, and/or other computer program components.

The well operation component 102 may be configured to obtain well operation information and/or other information. Obtaining well operation information may include one or more of accessing, acquiring, analyzing, determining, examining, generating, identifying, loading, locating, measuring, opening, receiving, retrieving, reviewing, selecting, storing, and/or otherwise obtaining the well operation information. The well operation component 102 may obtain well operation information from one or more locations. For example, the well operation component 102 may obtain well operation information from a storage location, such as the electronic storage 13, electronic storage of a device accessible via a network, and/or other locations. The well operation component 102 may obtain well operation information from one or more hardware components (e.g., a computing device, a sensor, a pressure sensor, a temperature sensor) and/or one or more software components (e.g., software running on a computing device). For example, the well operation component 102 may obtain well operation information by using one or more pressure sensors, one or more temperature sensors, and/or other sensors to determine/measure operation characteristics of a well.

The well operation information may characterize operation characteristics of a well for a duration of time. A well may refer to a hole that is drilled in the ground. A well may be drilled in the ground for exploration and/or recovery of resources in the ground, such as water or hydrocarbons. For example, a well may be drilled for production of hydrocarbons (e.g., as a production well). Operation characteristics of a well may refer to characteristics in the well during an operation that utilizes the well (e.g., for production). Operation characteristics of the well may refer to attribute, quality, configuration, parameter, and/or characteristics of matter inside, within, and/or around the well during an operation that utilizes the well.

For example, the operation characteristics of the well characterized by the well operation information may include pressure at the well, temperature at the well, and/or other operation characteristics of the well. Pressure at the well may include pressure measured by pressure sensors at multiple locations along the well. Temperature at the well may include temperature measured by temperature sensors at multiple locations along the well. For example, the operation characteristics of the well may include pressure and temperature measured downhole/at lower tubing (e.g., downhole pressure, downhole temperature), at annulus (e.g., annulus pressure, annulus temperature), at choke value (e.g., choke delta pressure, flowline pressure, flowline temperature), at upper tubing (e.g., tubing pressure, tubing temperature, tubing delta pressure, wellhead pressure, wellhead temperature), and/or other locations along the well. For instance, the operation characteristics of the well may include downhole pressure, flowline pressure, upstream and downstream subsea choke pressure, along with corresponding temperatures. Measurement of operation characteristics of the well at other locations is contemplated.

The well operation information obtained by the well operation component 102 may include real-time well operation information. Real-time well operation information may refer to well operation information that characterizes current operation characteristics of the well. For example, the real-time well operation information may characterize the operation characteristics of the well currently being measured by pressure sensors and temperature sensors. The real-time well operation information may characterize the operation characteristics of the well currently that has been measured within a threshold amount of time (e.g., operation characteristics measured within the past day/part of the past day). The duration of time for which the well operation information characterizes the operation characteristics of the well may include a set duration of time. The duration of time may be set by the system 10 (e.g., default duration of time) or set by a user (e.g., user-controlled duration of time). In some implementation, the duration of time may include a day or a part of a day. For example, pressure and temperature measured over the past day by the sensors may be obtained. Use of other durations of time is contemplated.

In some implementations, the well operation information may include a time-series data. For example, the well operation information may include a collection of pressure and temperature measurements at different time points within the duration of time.

The well operation information may characterize operation characteristics of a well by including information that defines, describes, delineates, identifies, is associated with, quantifies, reflects, sets forth, and/or otherwise characterizes one or more of value, property, quality, quantity, attribute, feature, and/or other aspects of the operation characteristics of the well. The well operation information may directly and/or indirectly characterize operation characteristics of a well. For example, the well operation information may characterize operating characteristics of a well by including information that specifies the type and/value of operation characteristics of the well and/or information that may be used to determine the type and/or value of operation characteristics of the well. Other types of well operation information are contemplated.

The reconstruction component 104 may be configured to determine reconstructed operation characteristics of the well for the duration of time. Determining reconstructed operation characteristics of the well may include ascertaining, approximating, calculating, establishing, estimating, finding, identifying, obtaining, quantifying, and/or otherwise determining the reconstructed operation characteristics of the well. The reconstruction component 104 may reconstruct the operation characteristics of the well for the duration of time. For example, the reconstruction component 104 may reconstruct pressure and temperature measured over the duration of time (e.g., past day, part of the day). The reconstruction component 104 may perform one-for-one reconstruction such that every pressure and temperature measurement over the duration of time is reconstructed.

The reconstructed operation characteristics of the well for the duration of time may be determined using one or more unsupervised machine-learning models. The unsupervised machine-learning model(s) may perform multivariate analysis to reconstruct the operation characteristics of the well. An unsupervised machine-learning model may refer to a machine-learning model that is not supervised using a training data. An unsupervised machine-learning model may refer to a machine-learning model that discovers hidden patterns and insights from the training data. An unsupervised machine-learning model may receive as input the operation characteristics of the well for the duration of time and may provide as output the reconstructed operation characteristics of the well for the duration of time.

In some implementations, the unsupervised machine-learning model(s) may include one or more linear unsupervised machine-learning model and/or one or more non-linear unsupervised machine-learning model. A linear unsupervised machine-learning model may provide/facilitate linear analysis of the training data and linear reconstruction of the input data. In some implementations, a linear unsupervised machine-learning model may include a principal component analysis. A non-linear unsupervised machine-learning model may provide/facilities non-linear analysis of the training data and non-linear reconstruction of the input data. In some implementations, a non-linear unsupervised machine-learning model may include a long short-term memory autoencoder. Use of other types of unsupervised machine-learning model is contemplated.

In some implementation, multiple unsupervised machine-learning models may be used to reconstruct the operation characteristics of the well. For example, a linear unsupervised machine-learning model and a non-linear unsupervised machine-learning model may be used to reconstruct the operation characteristics of the well. The reconstruction of the operation characteristics may be performed by the multiple unsupervised machine-learning models in parallel.

The unsupervised machine-learning model(s) may be trained using historical well operation information and/or other information. The historical well operation information may characterize the operation characteristics of the well for one or more periods of time preceding the duration of time. Historical well operation information may refer to well operation information that characterizes past operation characteristics of the well. For example, the historical well operation information may characterize the past operation characteristics of the well over a period of time that extends beyond a threshold amount of time (e.g., operation characteristics measured over six months to a year). The period for which the historical well operation information characterizes the past operation characteristics of the well may include a set period of time. The period of time may be set by the system 10 (e.g., default period of time) or set by a user (e.g., user-controlled period of time). In some implementations, the period of time may range between a half a year to a year. For example, pressure and temperature measured over a half a year to a year may be obtained. Use of other periods of time is contemplated.

In some implementations, one or more pre-processing steps may be applied to the historical well operation information before the historical well operation information is used to train the unsupervised machine-learning model(s). The pre-processing step(s) may prepare the historical well operation information for use in training the unsupervised machine-learning model(s). The pre-processing step(s) may remove undesired parts of the historical well operation information so that the undesired parts are not used to train the unsupervised machine-learning model(s).

For example, the pre-processing step(s) may include data smoothing, outlier removal, non-standard operation removal, continuous operation identification, and/or other processing step(s). Data smoothing may include removal of noise from the historical well operation information. For example, the historical well operation information may include high frequency data (e.g., temperature and pressure sampled every five seconds), and noise may exist within the historical well operation information due to operations of the well and/or sensor noise. The high-frequency data may be smoothed by downsampling the data (e.g., to one-minute interval) and applying a smoothing function (e.g., locally weighted scatterplot smoothing function) to the downsampled data.

Outlier removal may include removal of data points that fall outside the expected values of the data points. For example, temperature and/or pressure measurement that exceed the expected temperature and/or pressure may be removed from the historical well operation information.

Non-standard operation removal may refer to removal of data points that were measured when non-standard operation(s) were being conducted at the well. A non-standard operation may refer to an operation that deviates from a standard production operation. For example, data points in the historical well operation information during well closure, choking, ramping, and/or sanding events may be removed from the historical well operation information.

Continuous operation identification may refer to identification of data points that were measured when the well was in continuous standard operation for a threshold duration of time. Parts of the historical well operation information that include temperature and/or pressure measurement during continuous operation of the well may be identified for use in training the unsupervised machine-learning model(s). Use of other pre-processing steps is contemplated.

Training of an unsupervised machine-learning model using the historical information (e.g., temperature and/or pressure data points that remain after pre-processing) may result in the unsupervised machine-learning model discovering correlations between the historical information. Based on processing of the historical information, the unsupervised machine-learning model may determine model weights to be used for reconstruction of operation characteristics. When operation characteristics of a well are input to the unsupervised machine-learning model, the model weights may be used to reconstruct the operation characteristics of the well. The unsupervised machine-learning model may utilize the model weights to perform projection on the operation characteristics that are input to the unsupervised machine-learning model (e.g., perform projection on the real-time temperature and/or pressure data). In some implementations, one or more pre-processing steps, such as the pre-processing step(s) applied to the historical well operation information, may be applied to the well operation information before the well operation information is input to the unsupervised machine-learning model for reconstruction.

In some implementations, the unsupervised machine-learning model(s) may be retrained using the well operation information and/or other information. When the well operation information (real-time temperature and/or pressure data) is obtained, the well operation information may be added to the training data (after pre-processing) to retrain the unsupervised machine-learning model(s). The unsupervised machine-learning model(s) may adjust the model weights during the retraining.

The prediction component 106 may be configured to predict a future occurrence of a sanding event at the well. Predicting a future occurrence of a sanding event at the well may include determining that the sanding event will occur at the well in the future. Predicting a future occurrence of a sanding event at the well may include determining that the sanding event is likely to occur at the well in the future (e.g., determining that there is more than a threshold percentage of likelihood of the sanding event occurring at the well in the future). The sanding event may be predicted to occur within a certain duration of time (e.g., within a day, within hours, within an hour, within minutes, within a minute).

The future occurrence of the sanding event at the well may be predicted based on the operation characteristics of the well for the duration of time, the reconstructed operation characteristics of the well for the duration of time, and/or other information. The operation characteristics of the well and the reconstructed operation characteristics of the well for the same duration of time may be used to predict the future occurrence of the sanding event at the well. For example, the real-time temperature and pressure at the well and the reconstructed real-time temperature and pressure at the well over the same duration of time may be used to determine whether the sanding event will happen at the well in the future.

Comparison between the operation characteristics of the well and the reconstructed operation characteristics of the well may be used to determine whether the sanding event will happen at the well in the future. A trend of comparison between the operation characteristics of the well and the reconstructed operation characteristics of the well may be used to determine whether the sanding event will happen at the well in the future. For example, no sanding event may be predicted to occur in the future based on a trend of the reconstructed operation characteristics following the operation characteristics of the well. A sanding event may be predicted to occur in the future based on a trend of the reconstructed operation characteristics deviating from the operation characteristics of the well.

In some implementations, prediction of the future occurrence of the sanding event at the well based on the operation characteristics of the well for the duration of time and the reconstructed operation characteristics of the well for the duration of time may include a comparison between an anomaly score and an anomaly score threshold. An anomaly score for the well may indicate an extent to which the reconstructed operation characteristics deviating from the operation characteristics of the well. The anomaly score for the well may be determined based on a difference between the operation characteristics of the well for the duration of time and the reconstructed operation characteristics of the well for the duration of time, and/or other information. The difference between the operation characteristics of the well and the reconstructed operation characteristics of the well may be calculated using one or more statistical methods. For example, the difference between the operation characteristics of the well and the reconstructed operation characteristics of the well may be calculated as the mean absolute error, mean squared error of the operation characteristics and the reconstructed operation characteristics, and/or Mahalanobis distance between the operation characteristics and the reconstructed operation characteristics. For instance, the difference between the operation characteristics of the well and the reconstructed operation characteristics of the well may be calculated as the mean absolute error (MAE) using the following equation, where (xᵢ)=operation characteristic (e.g., measured temperature, measured pressure), (yᵢ)=reconstructed operation characteristics (e.g., reconstructed temperature, reconstructed pressure), and (n)=number of data points:

$$M A E = \frac{{\sum }_{i = 1}^{n} \vert {y}_{i} - {x}_{i} \vert}{n}$$

Use of other computation of the difference between the operation characteristics and the reconstructed operation characteristics is contemplated.

A future occurrence of a sanding event at the well may be predicted based on a comparison of the anomaly score and an anomaly score threshold, and/or other information. The anomaly score may be compared to the anomaly score threshold to determine whether the anomaly score exceeds the anomaly score threshold. A future occurrence of a sanding event at the well may be predicted based on the anomaly score exceeding the anomaly score threshold. The anomaly score exceeding the anomaly score threshold may indicate that the reconstructed operation characteristics have deviated sufficiently from the operation characteristics to predict a future occurrence of a sanding event.

In some implementation, a future occurrence of a sanding event at the well may be predicted based on the anomaly score exceeding the anomaly score threshold for a threshold duration of time. The anomaly score may need to exceed the anomaly score threshold for a certain duration of time before a future occurrence of a sanding event is predicted at the well. The threshold duration of time may be static or dynamic. For example, same threshold duration of time may be required regardless of the value by which the anomaly score exceeds the anomaly score threshold. As another example, a shorter threshold duration of time may be required to predict a sanding event when the anomaly score exceeds the anomaly score by a large value while a longer threshold duration of time may be required to predict a sanding event when the anomaly score exceeds the anomaly score by a small value.

In some implementations, the difference between the anomaly score and the anomaly score threshold may reflect the magnitude of the sanding event predicted in the future. A larger difference between the anomaly score and the anomaly score threshold may indicate that a larger sanding event will occur in the future (e.g., greater volume of sand entering the well) while a smaller difference between the anomaly score and the anomaly score threshold may indicate that a smaller sanding event will occur in the future (e.g., smaller volume of sand entering the well).

In some implementations, the anomaly score threshold may be determined based on the operation characteristics of the well for a period of time, reconstructed operation characteristics of the well for the period of time, and/or other information. The period of time may be the same as the period of time for which historical operation characteristics of the well is obtained for training. After the historical operation characteristics of the well is used to train an unsupervised machine-learning model, the historical operation characteristics of the well may be reconstructed by the unsupervised machine-learning model. The historical operation characteristics of the well and the reconstructed historical operation characteristics of the well may then be used to determine the anomaly score threshold. Comparison between the historical operation characteristics of the well and the reconstructed historical operation characteristics of the well may be used to determine the value of the anomaly score threshold.

The difference between the historical operation characteristics of the well and the reconstructed historical operation characteristics of the well may be used to determine the anomaly score threshold. The difference between the historical operation characteristics of the well and the reconstructed historical operation characteristics of the well may be calculated using one or more statistical methods (e.g., mean absolute error, mean squared error, Mahalanobis distance). The distribution of the difference (e.g., error distribution) between the historical operation characteristics and the reconstructed historical operation characteristics may be used to determine the anomaly score threshold. The distribution of the difference may be utilized to select the value of the anomaly score threshold so that a certain percentage of the distribution is below or above the anomaly score threshold. The value of the anomaly score threshold may be determined so that a threshold percentage of historical anomaly scores (difference between the historical operation characteristics and the reconstructed historical operation characteristics) satisfies (e.g., is below) the anomaly score threshold. For example, the value of the anomaly score threshold may be determined so that 90% of the historical anomaly score is below the anomaly score threshold. Use of other threshold percentage to determine the anomaly score threshold is contemplated.

In some implementations, the anomaly score threshold may be redetermined using the well operation information and/or other information. When the well operation information (real-time temperature and/or pressure data) is obtained, the operation characteristics of the well and the reconstructed operation characteristics of the well may be used to redetermine the anomaly score threshold. The value of the anomaly score threshold may be adjusted based on the difference between the operation characteristics of the well and the reconstructed operation characteristics of the well. The anomaly score threshold may be determined based on the distribution of the difference between the historical operation characteristics of the well and the reconstructed historical operation characteristics of the well, as well the distribution of the difference between the operation characteristics of the well and the reconstructed operation characteristics of the well.

In some implementations, one or more visualizations of the comparison between the anomaly score and the anomaly score threshold may be presented on one or more displays. A visualization of the comparison between the anomaly score and the anomaly score threshold may include visual/graphical representation of the anomaly score and the anomaly score threshold. In some implementations, the anomaly score and the anomaly score threshold may be stored in electronic storage (e.g., database, data server), and the stored values may be accessed by a visualization tool/software to generate and/or present the visualization.

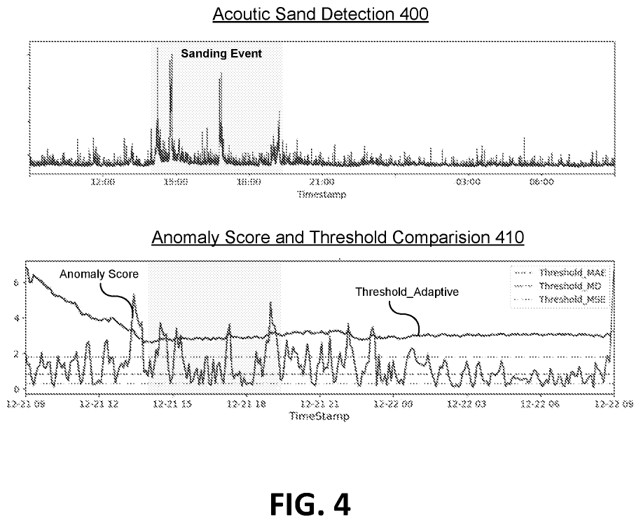

FIG. 4 illustrates example acoustic sand detection 400 and visualization 410 of comparison between anomaly score and anomaly score threshold for sanding event prediction. The acoustic sand detection 400 may have identified a sanding event starting around the 14th hour on December 21st. The visualization 410 may include a plot of the anomaly score, along with plots of anomaly score threshold calculated using different approaches: (1) mean absolute error, (2) Mahalanobis distance, and (3) mean squared error. The plots of anomaly score threshold may also include a plot that shows adaptive anomaly score threshold that is adjusted using well operation characteristics and reconstructed well operation characteristics. As shown in FIG. 4, a sanding event may have occurred about an hour after the anomaly score rose above the adaptive anomaly score threshold. The present disclosure would have predicted this sanding event an hour in advance and would have enabled preventative/mitigative measures to be taken at the well.

In some implementations, prediction of future sanding event at the well may be used to facilitate monitoring of the well/equipment at the well. An acoustic sand detector used to detect sanding event that has occurred at the well may be inaccurate. The prediction of future sanding event using the operation characteristics of the well and the reconstructed operation characteristics of the well may be used to replace or complement the sanding event detection performed by an acoustic sand detector. For example, the acoustic sand detector may not accurately detect small quantities of sanding, while the prediction of future sanding event using the operation characteristics of the well and the reconstructed operation characteristics of the well may be able to accurately predict small sanding events.

Sanding events may result in erosion of the well/equipment at the well. For example, the movement of sand may erode the metal (e.g., steel) inside a choke of the well. The prediction of future sanding event at the well may be used to track wear on the well/equipment at the well and/or predict failure/remaining lifetime of the well/equipment at the well. For instance, based on the number, magnitude, and/or regularity of sanding events that are predicted at the well, the wear on the well/equipment at the well may be estimated. Based on the number, magnitude, and/or regularity of sanding events that are predicted at the well, remaining life of the well/equipment at the well may be estimated. Other use of the prediction of future sanding event at the well is contemplated.

Implementations of the disclosure may be made in hardware, firmware, software, or any suitable combination thereof. Aspects of the disclosure may be implemented as instructions stored on a machine-readable medium, which may be read and executed by one or more processors. A machine-readable medium may include any mechanism for storing or transmitting information in a form readable by a machine (e.g., a computing device). For example, a tangible computer-readable storage medium may include read-only memory, random access memory, magnetic disk storage media, optical storage media, flash memory devices, and others, and a machine-readable transmission media may include forms of propagated signals, such as carrier waves, infrared signals, digital signals, and others. Firmware, software, routines, or instructions may be described herein in terms of specific exemplary aspects and implementations of the disclosure, and performing certain actions.

In some implementations, some or all of the functionalities attributed herein to the system 10 may be provided by external resources not included in the system 10. External resources may include hosts/sources of information, computing, and/or processing and/or other providers of information, computing, and/or processing outside of the system 10.

Although the processor 11, the electronic storage 13, and the display 14 are shown to be connected to the interface 12 in FIG. 1, any communication medium may be used to facilitate interaction between any components of the system 10. One or more components of the system 10 may communicate with each other through hard-wired communication, wireless communication, or both. For example, one or more components of the system 10 may communicate with each other through a network. For example, the processor 11 may wirelessly communicate with the electronic storage 13. By way of non-limiting example, wireless communication may include one or more of radio communication, Bluetooth communication, Wi-Fi communication, cellular communication, infrared communication, or other wireless communication. Other types of communications are contemplated by the present disclosure.

Although the processor 11, the electronic storage 13, and the display 14 are shown in FIG. 1 as single entities, this is for illustrative purposes only. One or more of the components of the system 10 may be contained within a single device or across multiple devices. For instance, the processor 11 may comprise a plurality of processing units. These processing units may be physically located within the same device, or the processor 11 may represent processing functionality of a plurality of devices operating in coordination. The processor 11 may be separate from and/or be part of one or more components of the system 10. The processor 11 may be configured to execute one or more components by software; hardware; firmware; some combination of software, hardware, and/or firmware; and/or other mechanisms for configuring processing capabilities on the processor 11.

It should be appreciated that although computer program components are illustrated in FIG. 1 as being co-located within a single processing unit, one or more of computer program components may be located remotely from the other computer program components. While computer program components are described as performing or being configured to perform operations, computer program components may comprise instructions which may program processor 11 and/or system 10 to perform the operation.

While computer program components are described herein as being implemented via processor 11 through machine-readable instructions 100, this is merely for ease of reference and is not meant to be limiting. In some implementations, one or more functions of computer program components described herein may be implemented via hardware (e.g., dedicated chip, field-programmable gate array) rather than software. One or more functions of computer program components described herein may be software-implemented, hardware-implemented, or software and hardware-implemented.

The description of the functionality provided by the different computer program components described herein is for illustrative purposes, and is not intended to be limiting, as any of computer program components may provide more or less functionality than is described. For example, one or more of computer program components may be eliminated, and some or all of its functionality may be provided by other computer program components. As another example, processor 11 may be configured to execute one or more additional computer program components that may perform some or all of the functionality attributed to one or more of computer program components described herein.

The electronic storage media of the electronic storage 13 may be provided integrally (i.e., substantially non-removable) with one or more components of the system 10 and/or as removable storage that is connectable to one or more components of the system 10 via, for example, a port (e.g., a USB port, a Firewire port, etc.) or a drive (e.g., a disk drive, etc.). The electronic storage 13 may include one or more of optically readable storage media (e.g., optical disks, etc.), magnetically readable storage media (e.g., magnetic tape, magnetic hard drive, floppy drive, etc.), electrical charge-based storage media (e.g., EPROM, EEPROM, RAM, etc.), solid-state storage media (e.g., flash drive, etc.), and/or other electronically readable storage media. The electronic storage 13 may be a separate component within the system 10, or the electronic storage 13 may be provided integrally with one or more other components of the system 10 (e.g., the processor 11). Although the electronic storage 13 is shown in FIG. 1 as a single entity, this is for illustrative purposes only. In some implementations, the electronic storage 13 may comprise a plurality of storage units. These storage units may be physically located within the same device, or the electronic storage 13 may represent storage functionality of a plurality of devices operating in coordination.

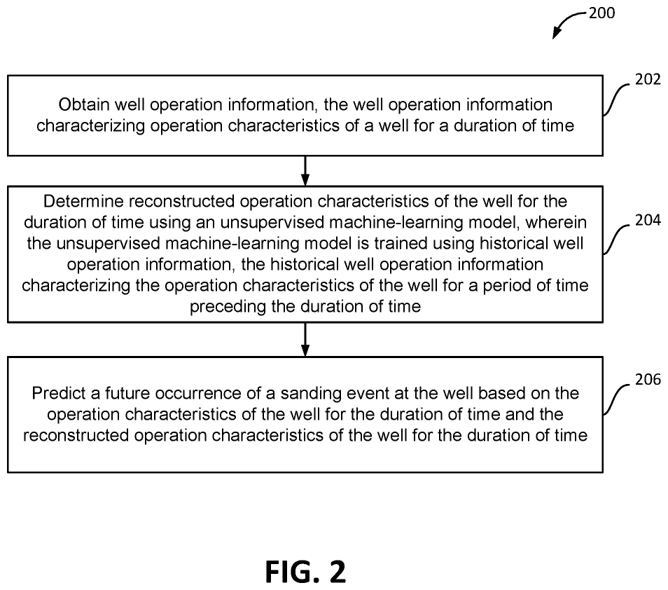

FIG. 2 illustrates method 200 for predicting sanding events. The operations of method 200 presented below are intended to be illustrative. In some implementations, method 200 may be accomplished with one or more additional operations not described, and/or without one or more of the operations discussed. In some implementations, two or more of the operations may occur substantially simultaneously.

In some implementations, method 200 may be implemented in one or more processing devices (e.g., a digital processor, an analog processor, a digital circuit designed to process information, a central processing unit, a graphics processing unit, a microcontroller, an analog circuit designed to process information, a state machine, and/or other mechanisms for electronically processing information). The one or more processing devices may include one or more devices executing some or all of the operations of method 200 in response to instructions stored electronically on one or more electronic storage media. The one or more processing devices may include one or more devices configured through hardware, firmware, and/or software to be specifically designed for execution of one or more of the operations of method 200.

Referring to FIG. 2 and method 200, at operation 202, well operation information and/or other information may be obtained. The well operation information may characterize operation characteristics of a well for a duration of time. In some implementation, operation 202 may be performed by a processor component the same as or similar to the well operation component 102 (Shown in FIG. 1 and described herein).

At operation 204, reconstructed operation characteristics of the well for the duration of time may be determined using an unsupervised machine-learning model. The unsupervised machine-learning model may be trained using historical well operation information and/or other information. The historical well operation information may characterize the operation characteristics of the well for a period of time preceding the duration of time. In some implementation, operation 204 may be performed by a processor component the same as or similar to the reconstruction component 104 (Shown in FIG. 1 and described herein).

At operation 206, a future occurrence of a sanding event at the well may be predicted based on the operation characteristics of the well for the duration of time, the reconstructed operation characteristics of the well for the duration of time, and/or other information. In some implementation, operation 206 may be performed by a processor component the same as or similar to the prediction component 106 (Shown in FIG. 1 and described herein).

Although the system(s) and/or method(s) of this disclosure have been described in detail for the purpose of illustration based on what is currently considered to be the most practical and preferred implementations, it is to be understood that such detail is solely for that purpose and that the disclosure is not limited to the disclosed implementations, but, on the contrary, is intended to cover modifications and equivalent arrangements that are within the spirit and scope of the appended claims. For example, it is to be understood that the present disclosure contemplates that, to the extent possible, one or more features of any implementation can be combined with one or more features of any other implementation.

What is claimed is:

1. A system for predicting sanding events, the system comprising:
one or more physical processors configured by machine-readable instructions to:
obtain well operation information, the well operation information characterizing operation characteristics of a well for a duration of time;
determine reconstructed operation characteristics of the well for the duration of time using an unsupervised machine-learning model, wherein the unsupervised machine-learning model is trained using historical well operation information, the historical well operation information characterizing the operation characteristics of the well for a period of time preceding the duration of time; and
predict a future occurrence of a sanding event at the well based on the operation characteristics of the well for the duration of time and the reconstructed operation characteristics of the well for the duration of time.

2. The system of claim 1, wherein the unsupervised machine-learning model includes a linear unsupervised machine-learning model and/or a non-linear unsupervised machine-learning model.

3. The system of claim 1, wherein the linear unsupervised machine-learning model includes a principal component analysis.

4. The system of claim 1, wherein the non-linear unsupervised machine-learning model includes a long short-term memory autoencoder.

5. The system of claim 1, wherein prediction of the future occurrence of the sanding event at the well based on the operation characteristics of the well for the duration of time and the reconstructed operation characteristics of the well for the duration of time includes:
determination of an anomaly score based on a difference between the operation characteristics of the well for the duration of time and the reconstructed operation characteristics of the well for the duration of time; and
prediction of the future occurrence of the sanding event at the well based on a comparison between the anomaly score and an anomaly score threshold.

6. The system of claim 5, wherein the anomaly score threshold is determined based on the operation characteristics of the well for the period of time and reconstructed operation characteristics of the well for the period of time.

7. The system of claim 6, wherein the anomaly score threshold is determined based on the operation characteristics of the well for the period of time and reconstructed operation characteristics of the well for the period of time such that a threshold percentage of historical anomaly scores satisfies the anomaly score threshold.

8. The system of claim 1, wherein the one or more physical processors are further configured by the machine-readable instructions to present a visualization of the comparison between the anomaly score and the anomaly score threshold.

9. The system of claim 1, wherein the unsupervised machine-learning model is retrained using the well operation information.

10. The system of claim 1, wherein the operation characteristics of the well includes pressure and temperature at the well.

11. A method for predicting sanding events, the method comprising:
obtaining well operation information, the well operation information characterizing operation characteristics of a well for a duration of time;
determining reconstructed operation characteristics of the well for the duration of time using an unsupervised machine-learning model, wherein the unsupervised machine-learning model is trained using historical well operation information, the historical well operation information characterizing the operation characteristics of the well for a period of time preceding the duration of time; and
predicting a future occurrence of a sanding event at the well based on the operation characteristics of the well for the duration of time and the reconstructed operation characteristics of the well for the duration of time.

12. The method of claim 11, wherein the unsupervised machine-learning model includes a linear unsupervised machine-learning model and/or a non-linear unsupervised machine-learning model.

13. The method of claim 11, wherein the linear unsupervised machine-learning model includes a principal component analysis.

14. The method of claim 11, wherein the non-linear unsupervised machine-learning model includes a long short-term memory autoencoder.

15. The method of claim 11, wherein predicting the future occurrence of the sanding event at the well based on the operation characteristics of the well for the duration of time and the reconstructed operation characteristics of the well for the duration of time includes:
determining an anomaly score based on a difference between the operation characteristics of the well for the duration of time and the reconstructed operation characteristics of the well for the duration of time; and
predicting the future occurrence of the sanding event at the well based on a comparison between the anomaly score and an anomaly score threshold.

16. The method of claim 15, wherein the anomaly score threshold is determined based on the operation characteristics of the well for the period of time and reconstructed operation characteristics of the well for the period of time.

17. The method of claim 16, wherein the anomaly score threshold is determined based on the operation characteristics of the well for the period of time and reconstructed operation characteristics of the well for the period of time such that a threshold percentage of historical anomaly scores satisfies the anomaly score threshold.

18. The method of claim 11, further comprising presenting a visualization of the comparison between the anomaly score and the anomaly score threshold.

19. The method of claim 11, wherein the unsupervised machine-learning model is retrained using the well operation information.

20. The method of claim 11, wherein the operation characteristics of the well includes pressure and temperature at the well.
